(19) United States
(12) Patent Application Publication
(10) Pub. No.: US 2007/0230861 A1
(43) Pub. Date: Oct. 4, 2007

(54) Laser Inscribed Structures

(76) Inventors: Igor Khrushchev, Birmingham (GB); Yicheng Lai, Birmingham (GB); Mykhaylo Dubov, Birmingham (GB); Amos Martinez, Birmingham (GB); Ian Bennion, Birmingham (GB)

Correspondence Address: LAW OFFICE OF JAMES TROSINO, 92 NATOMA STREET, SUITE 211, SAN FRANCISCO, CA, 94105, US

(21) Appl. No.: 11/569,119

(22) PCT Filed: May 16, 2005
(86) PCT No.: PCT/GB05/01869

§ 371 Date: Mar. 26, 2007

(30) Foreign Application Priority Data
May 14, 2004 (GB) 0410821.3

(51) Int. Cl. G02B 6/028; G02B 6/34; G03F 7/20

(52) U.S. Cl. 385/13; 385/124; 385/37; 430/321

(57) ABSTRACT

An optical fiber or waveguide having a core and a cladding, the fiber/waveguide including a modified region or regions with a modified optical property that differs from the surrounding optical fiber/waveguide, wherein the cross sectional area of the modified region(s) is considerably smaller than the cross sectional area of the core of the fiber or waveguide.

This invention relates to optical fibers and wave guides, in particular those containing gratings such as fiber Bragg gratings and long period gratings.

It is known to use laser inscription in transparent dielectric material such as bulk glass and optical fibers. In particular it is known to fabricate fiber gratings using this technique including directly written high order of fiber Bragg gratings and long period gratings, fiber Bragg gratings produced using special phase-masks or produced by a femtosecond UV laser with a standard phase mask.

Normally fabricating fiber gratings requires the removal and re-application of the plastic coating that surrounds conventional fiber. There are known methods which attempt to avoid such removal. The UV inscription through the cladding can be carried out by deliberately using a longer-wavelength (near-UV) light in the spectral range of 300 nm to 364 nm. However, the method requires very high doping concentrations, as the fiber photosensitivity in this range is lower than that in commonly used spectral window 244 nm to 248 nm. This also means that dedicated phase masks, designed for the longer wavelength, are required. Alternatively, inscription at one of the conventional, shorter wavelengths (244 nm to 248 nm) can be used in combination with a dedicated coating, transparent in this range. Again, a need for a specialist fiber contributes to the higher cost of the technique.

It is also known to provide strain sensors which use fiber Bragg gratings. These sensors make use of the fact that the reflected wavelength of the grating will vary with strain and measure strain by analysing the change in this reflective wavelength. The fiber Bragg gratings used in such sensors are conventionally made by UV radiation.

Normally, such strain sensors cannot detect the direction of the strain since the change in wavelength will be the same whatever the direction of the strain. It is also known to provide a so-called direction sensitive strain sensor in which the direction of the strain can be detected. This can be done by making the grating asymmetrically positioned relative to the centre of the fiber. Two known methods of producing these are by using a multi-core fiber or using a fiber with asymmetric cladding such as a D shaped fiber. Both of these methods require unconventional fibers which are costly and demand special coupling techniques. There methods cannot be used to produce directional strain sensors using standard single core fibers.

It is also known to provide a bending sensor using the properties of fiber Bragg gratings. In order to detect a changing reflected wavelength on the bending of the fiber it is generally necessary to have the grating asymmetrically positioned relative to the centre of the fiber. Suitable sensors with multicore or D shaped fibers can measure the bending of an object on which the fiber is attached. These are normally non-directional bending sensors detecting the curvature but not the direction of the bending. It is also known to provide so-called vectorial bending sensors which can particularise the direction of the bending. However, again these require either multi-core fibers or asymmetric D shaped fibers. Additionally, they are only able to detect directional change in a single plane and therefore can only be said to be 1D vectorial bending sensors and not 2D.

An additional problem with fiber Bragg gratings is that the structures of different refractive index of which they are comprised can be erased by light. Regions produced by UV radiation are particularly prone to erasure. This can create significant problems since in use light is directed down the core in which the structures are present.

It is also known to provide superimposed gratings. Superimposed gratings are a very useful passive optical device for a number of important applications. For instance they allow for wavelength division multiplexing (WPM) using superimposing Bragg gratings of different Bragg wave lengths.

Unfortunately, known Bragg gratings have such transverse size that each grating occupies all or most of the fiber core cross section. Therefore, superimposed gratings overlap physically and hence the structures are affected by physical interactions between them decreasing the accuracy of such structures.

It is also known to provide long period gratings in the above applications. An LPG is like an FBG with a section of periodic changes in the refractive index at the core of the optical fiber but with a much longer period that is typically between 100 microns and 1 mm. The LPG couples light from the propagating mode the fiber to modes associate the cladding of the fiber. As a result the transition spectrum of an LPG consists of a series of attenuation bands corresponding to the coupling of the propagating mode to the cladding mode.

It is an object of the present invention to mitigate some or all of the above problems.

According to a first aspect of the invention there is provided an optical fiber or waveguide having a core and a cladding, the fiber/waveguide including a modified region or regions with a modified optical property that differs from the surrounding optical fiber/waveguide, wherein the cross sectional area of the modified region(s) is considerably smaller than the cross sectional area of the core of the fiber or waveguide.

According to a second aspect of the invention there is provided an optical fiber or waveguide having a core and a cladding, the fiber/waveguide comprising a modified region in the cladding, the region having a modified optical property that differs from the surrounding cladding, wherein a non-modified section of the core in the vicinity of modified region has effective optical properties different to the surrounding core.

An embodiment of the invention will now be described by way of example only, with reference to the accompanying drawings in which

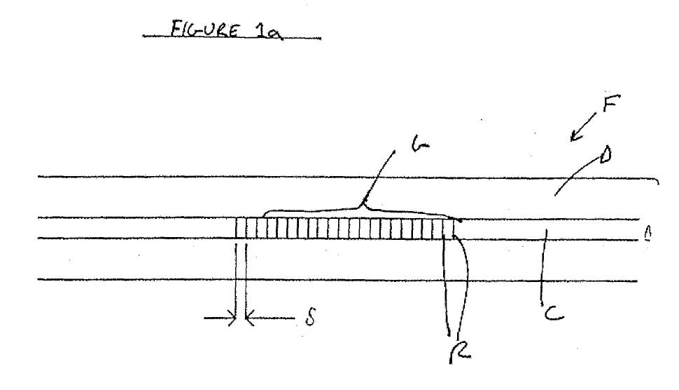

FIG. 1a is a schematic view of longitudinal section of a prior art fiber Bragg grating sensor;

FIG. 1b is a profile of the refractive index of the grating of the prior art fiber in FIG. 1a;

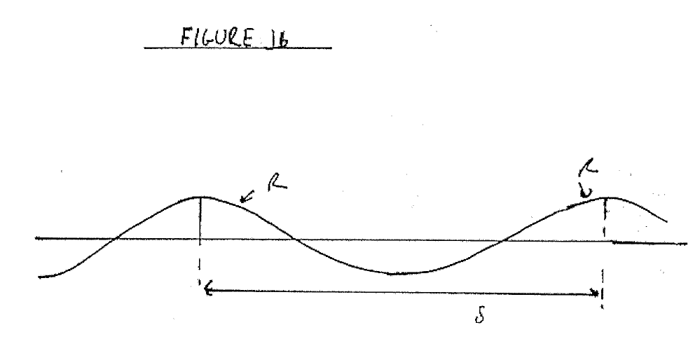

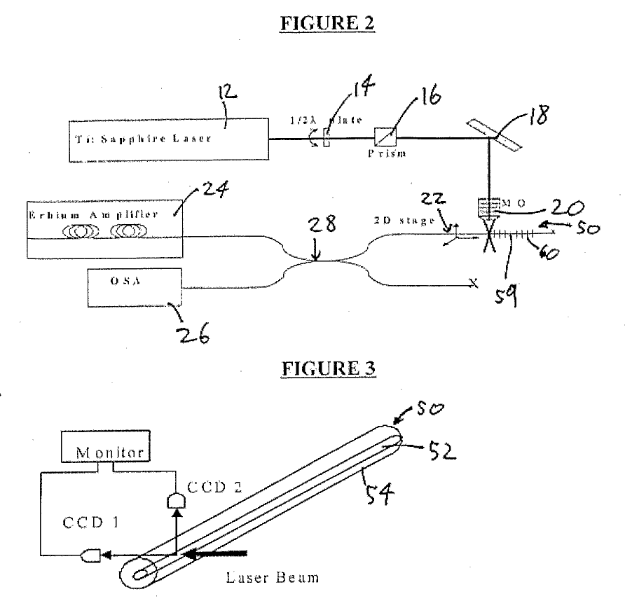

FIG. 2 is a system for inscribing regions such as a grating in the fiber in accordance with the invention;

FIG. 3 is schematic drawing of monitoring the refractive index in an inscribed grating according to the invention;

FIG. 4 is a profile of the refractive index of the grating produced by the system of FIG. 2;

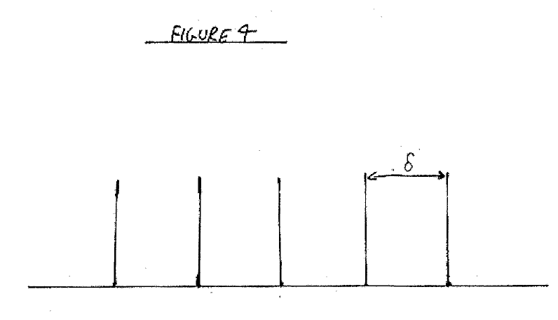

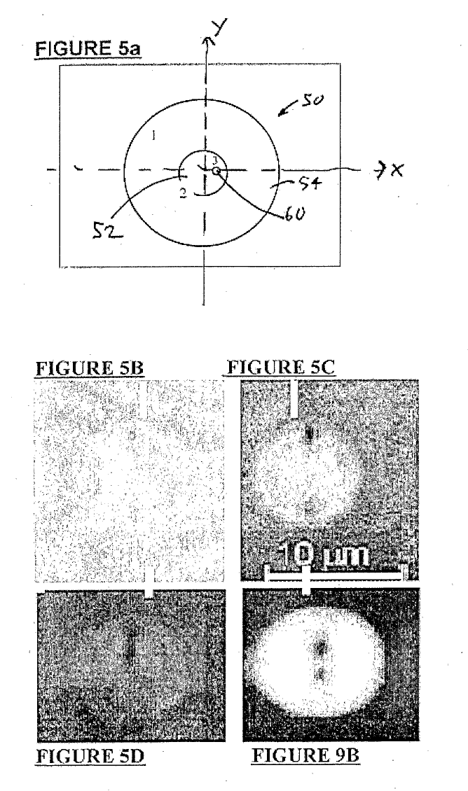

FIG. 5a is a schematic cross-sectional view of an inscribed optical fiber according to the invention;

FIGS. 5b to 5d are photographs of cross-sections of various inscribed gratings similar to those as depicted FIG. 4a;

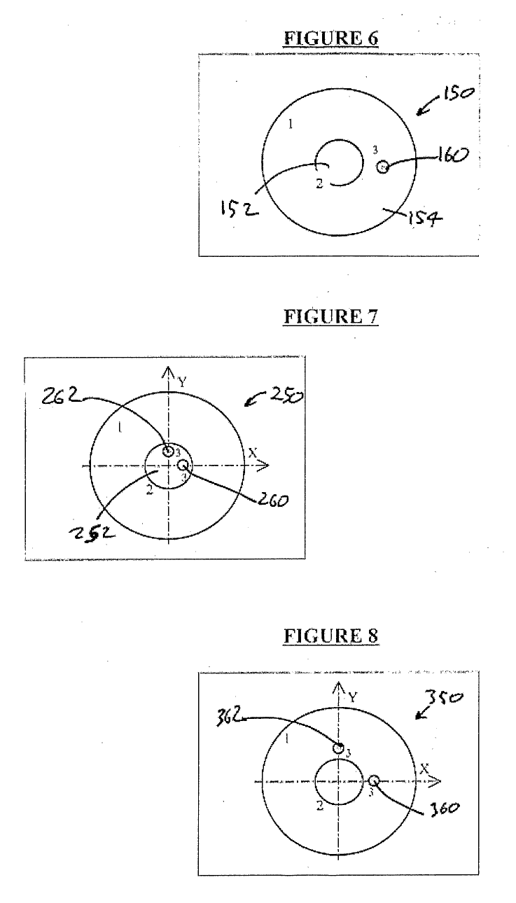

FIG. 6 is a schematic cross-sectional view of a second embodiment of optical fiber according to the invention with the modified volume outside of the core;

FIG. 7 is a schematic cross-sectional view of a third embodiment of optical fiber according to the invention containing two modified volumes;

FIG. 8 is a schematic cross-sectional view of a fourth embodiment of optical fiber according to the invention with multiple gratings located outside the core;

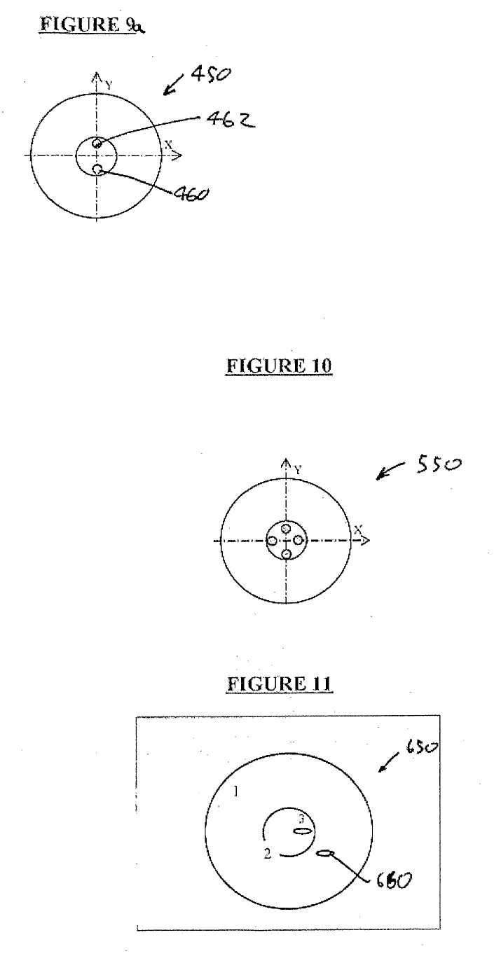

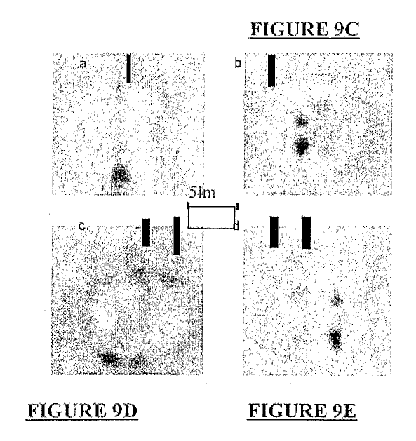

FIG. 9a is a schematic cross-sectional view of a fifth embodiment of optical fiber according to the invention;

FIGS. 9b to 9e are photographs of fiber optic according to the invention with two gratings similar to that depicted in FIG. 9a;

FIG. 10 is a schematic cross-sectional view of sixth embodiment of optical fiber according to the invention;

FIG. 11 is a schematic cross-sectional view of a seventh embodiment of optical fiber according to the invention;

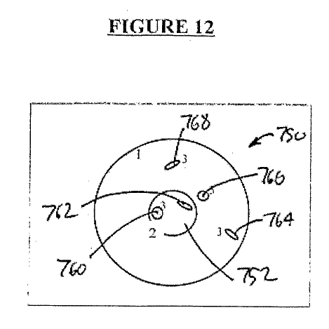

FIG. 12 is a schematic cross-sectional view of a of an eight embodiment of optical fiber according to the invention;

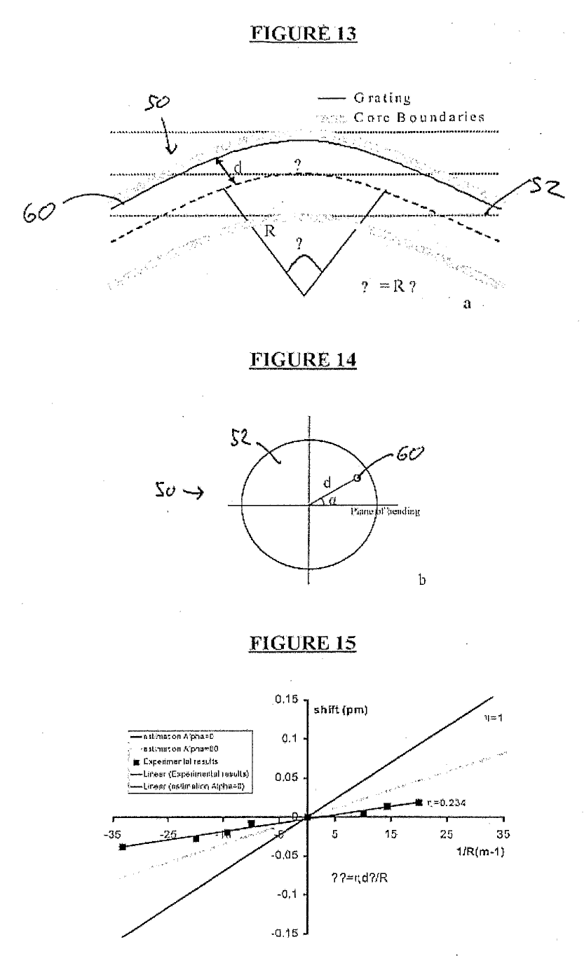

FIG. 13 is a cross-sectional longitudinal section of a bent fiber optic inscribed grating;

FIG. 14 is a cross-sectional view of the fiber of FIG. 19;

FIG. 15 is a graph of the inverse of the radius of curvature against the change in reflected wavelength of a fiber similar to the one illustrated in FIGS. 13 and 14;

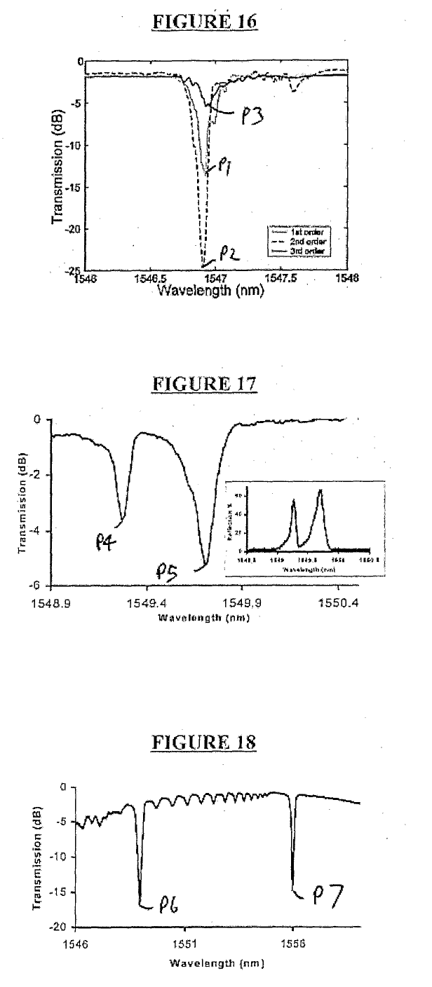

FIG. 16 is a transition spectra for first, second and third order gratings inscribed in an optical fiber in accordance with the invention;

FIGS. 17 and 18 are transmission reflection spectra of double gratings in cross-section similar to FIG. 9;

FIG. 19 is a graph of birefringence of a fiber Bragg grating according to the invention showing greater resonance shift than that in UV inscribed structures; and

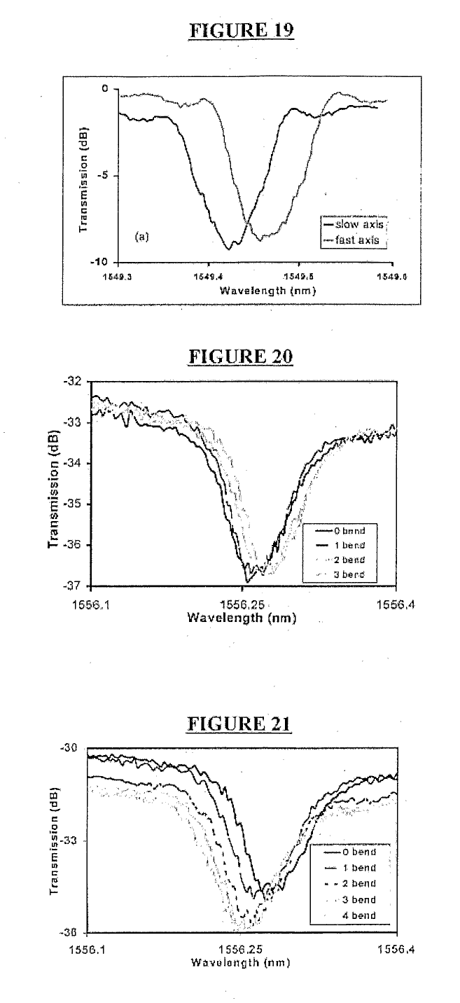

FIGS. 20 and 21 shows the spectral shift in vectorial sensor based on a single off-set axis fiber Bragg grating;

Referring to FIG. 1a there is shown a prior art fiber Bragg grating F comprising a core C in cladding D. Within the core is a Bragg grating G comprising regions of higher refractive index R the centres of which are each separated by a distance δ representing the period of the grating. Each region R extends across the full width and height of the core C.

The regions are usually made by illuminating the core C with a pattern of intense UV laser light. This alters the structure of the fiber and increases its refractive index slightly. In order to create a Bragg grating it is necessary to produce a periodic variation in refractive index. This periodic variation of refractive index of the fiber may be produced by a spatial variation of intensive UV light caused by the interference of two coherent beams or a mask placed over the fiber.

In FIG. 1b is shown a profile of the refractive index in the altered region of the grating G. It can be seen that there is a substantially sinusoidal variation in the refractive index with the distance δ between each peak R. Thus δ corresponds to the period of the grating.

The modified fiber Bragg grating F acts as a wavelength selected mirror. When light is transmitted through the core C, light at one particular wavelength or narrow range of wave lengths is returned down the fiber. This wavelength is altered by the temperature and axial strain and therefore fiber Bragg gratings can be used to measure change in both of these conditions.

In FIG. 2 is shown a system 10 in accordance with the invention for femtosecond inscribing of modified regions in optical fiber. The system 10 comprises a laser 12; half wavelength plate 14 and a polariser 16 forming together a variable attenuator; mirror 18; objective 20; XY stage 22; a broadband light source 24; a coupler 28 and two optical spectrum analysers 26. A section of an optical fiber 50 is stretched between two fiber holders, mounted on 3-D translation stages. The assembly including stages with the holders is mounted on the computer controlled XY stage 22 with nanometre accuracy.

In this example, the laser 12 is operated at a wavelength of 800 nm, producing 150 femtosecond long pulses at a repetition rate of 1 kHz. No special preparation of the fiber is needed and no mask needs to be used. Plastic coating is removed from the stretched section of the fiber prior to the exposure.

Both ends of the stretched section of the fiber are aligned independently in both perpendicular dimensions of the fiber 50 and alignment through the fiber is assessed by monitoring scans between these ends. The fiber 50, shown in FIG. 3, is positioned when the laser beam is considerably attenuated to a level well below inscription threshold in order to avoid damage in the fiber 50.

The position of the laser's focal point inside the fiber in horizontal plane and in vertical plane is monitored by using two orthogonal placed CCD cameras with integrated long-distance microscopes as shown in FIG. 3.

The writing process of the invention involves focusing very tightly the femtosecond laser beam into areas of the core of fiber 50. The beam radius in the focal spot can be estimated from the equation:

$$ω = \frac{0.61 λ ( μ m )}{NA}$$

For example, using a numerical aperture NA=0.65 and 100X objective 20 allows the beam to be focused into a spot size as small as 1 lm with the wavelength of 800 nm. The spot size can be further reduced by changing the operating wavelength from infrared region to visible region or to ultraviolet region. This can be achieved, for example, by converting the fundamental harmonics (λ=800 nm) into the second harmonics (λ=400 nm) or higher harmonics of the fundamental laser wavelength by using nonlinear crystals, such as Li:NiO₃. An alternative method is to control the power of the laser in such a way that intensity in the central part of the beam reaches the value above the inscription threshold, whilst the intensity at the edges of the beam remains below the threshold value. As a result, spatial resolution below the size of the focal spot can be achieved.

Once the inscribing starts the intensity of the laser must be above the “inscription” threshold for altering the refractive index of the fiber 50 but below the threshold of permanent optical damage. In order to produce a periodic structure such as a Bragg grating or long period grating the stage 22 is moved at a constant speed along the fiber 50 in sync with the pulse rate of the laser 12. By doing this each laser pulse produce a grating pitch 59 in the fiber core 52 at equally spaced distances a Bragg grating or long period grating 60 is produced.

The grating period produced is defined by a ratio of the translation speed of the stage 22 to the pulse repetition rate of the laser 12. The grating reflection transmission can be monitored in situ by using the two optical spectrum analysers 26 coupled to the amplifier 24.

A grating can also be produced by multiple pulses onto a single region and/or with a non-pulsed laser which is turned off to allow the fiber 50 to be moved position in order that the next grating pitch 59 can be inscribed.

A profile of the refractive index of a grating 60 inscribed by the above method is shown in FIG. 4. Each pitch 59 is high, narrow and substantially delta function like. Most of the period between each pitch comprises a region of substantially constant and often unmodified refractive index. This profile of sharply defined pitches 59 makes the grating 60 more efficient than those with a sinusoidal profile.

It is thought that the refractive index change caused by such femtosecond inscription is due to a material restructuring and localised compaction rather than by defect formation as is the case for standard UV inscription. This is one reason why it is believed that such an inscription method can be used in materials not usually regarded as photosensitive.

It is found that the grating 60 inscribed using this method has a higher thermal robustness than gratings inscribed by UV light. Grating 60 is stable up to 900 degrees compared to 400 or 700 as is typical of type 1 and 2a UV inscribed laser gratings, and grating 60 is not permanently damaged until the temperature goes over 1000 degrees. Further it seems that gratings 60 inscribed by this method have a greater stability against erasure by light, making them suitable for use with blue light and the UV spectrum. Due to the precise focusing ability of the set up described above regions of different refractive index can be created which are very small. They can have a diameter in the region of only 2 lm or even much less than 1 lm.

Referring to FIG. 5a there is shown a schematic view of a cross section of fiber 50 with the modified volumes 60 representing a periodic grating produced as described above. The modified region is in the core 52 rather than cladding 54 and only takes up a small fraction of its area. Fibre 50 therefore has an asymmetric distribution of refractive index and a different distribution of refractive index in plane X to in the plane Y.

In FIGS. 5b to d, are shown actual cross section pictures of various laterally displaced grating 60 produced with the above method and similar to fiber 50 illustrated in FIG. 5a. FIG. 5b shows a single grating 60 in a standard fiber inscribed using a 100 x objective 20. The fiber in FIG. 5c is produced with same methodology but in a dispersion compensation fiber. FIG. 4d shows a grating produced in a standard fiber but inscribed with a 40 x objective 22. Notably the grating in FIG. 4d has a larger cross sectional area than in FIG. 4b because of the focusing ability of the objective 20.

FIG. 6 shows a cross section of a fiber 150 in which a grating has been produced in the cladding 154 outside of the core 152. The modified region 160 is still close to the core 152, however.

It is known that modifying refractive index in a certain volume affects the effective refractive index in its surrounding locality. Consequently, because the modified region 160 is close to the core 152, the section of the core 152 that is closest to region 160 has a different refractive index from the rest of the core 152. The modified region 160 has been inscribed periodically and therefore there is an effective grating produced in a small section of the core 152.

Since the region 160 is outside of the core 152 in which light is transmitted the effect of light erasure on the region 160 is very small.

In FIG. 7 is shown a third embodiment of inscribed fiber 250. In fiber 250 the modified regions 260 and 262 are within the core 252, both of the modified regions 260 and 262 being considerably smaller than the core 262. In this example the first region 260 has been placed in plane X and the second grating 262 has been positioned in plane Y.

A fourth embodiment of fiber 350 is shown in FIG. 8. This example has been inscribed with modified regions 360 and 362 in the X plane and Y plane respectively in a similar manner to fiber 250 except that the regions 360, 362 are located in the cladding 154, and only the vicinity of the core 352. The effective refractive index in the sections of the core 352 nearest the modified regions 360 and 362 is consequently higher than in the rest of the core 352.

In FIG. 9a is shown another embodiment with two gratings both laterally disposed off centre but in the same plane, plane Y.

FIGS. 9b, c, d and e are shown as pictures of examples where two gratings have been inscribed within the fiber similar to the fiber shown in FIG. 9a. In FIG. 9b the fiber has two gratings inscribed in a standard fiber with a 100X objective, and a 3 μm separation between the two structures. In FIG. 9c the two gratings were separated by translation along the laser beam; in FIG. 9d by rotational displacement and in FIG. 9e by translation along and across the laser beam.

In FIGS. 17 and 18 are shown two examples of transmission and reflection spectra of double gratings cross sections similar to that depicted in FIG. 9b to e. These gratings are inscribed perpendicular to each other with a displacement of 3 micrometers from the centre of the fiber core. Distinct peaks P4, P5, P6, P7 can be seen at specific wavelengths with a line width sufficiently small that there is no overlap between bands of wavelengths reflected from the two gratings

In FIG. 10 is shown an embodiment with a pair of such off centre gratings on each of X plane and Y plane.

Such pairs of gratings as shown in FIGS. 9 and 10 can be produced by a parallel translation of the fiber in a lateral direction of the inscription or by rotating the fibers in respect to the axis.

In FIG. 11 is shown a fiber 550 with elliptical modified regions 560 and 562. Such non circular modified regions are capable of being created using the highly focused method of inscription inscribed above. Elliptical cross sections can be used to create birefringent properties in the fiber 550. Regions with highly elliptical cross-sections can be used to produce a single polarisation device.

In FIG. 19 is shown the birefringence of a fiber clad grating similar to fiber 550 with the reflective wavelength along the fast and slow axes.

It is useful to produce devices with an array of separated gratings. In particular it can be used for wavelength division multiplexing (WDM). Each of the gratings may have different Bragg wavelengths and when used with a broadband light source or a tuneable swept wavelength light source it is possible to increase the number of available channels within a fiber. Such devices can also be used as wavelength selective mirrors in multi wavelength fiber lasers.

Such structures can be produced more densely (allowing Dense WDM) by superimposing the gratings so that they overlap. The inscription of these dense structures is normally achieved by modifying the same volume of material several times for multiple gratings. As a result the number and density of gratings in a single fiber is limited by the physical interaction between the structures. It has been found that increasing the numbers of such gratings causes an increase in the spectral full width half maximum line width of each of the gratings. Additionally, the inscription of each additional grating causes the existing grating to shift to longer wavelengths possibly because of a change in the mean refractive index of the superimposed grating. Further the reflectivity of the grating is also found to decrease with an increase in the number of gratings made by conventional methods.

By using the tightly focused inscription method described above a number of gratings can be produced in different regions of the same cross section of fiber due to the smallness of the modified regions that can be created and their localised nature such grating structures can be physically separated from each other laterally avoiding the problems caused by physical interaction between them. Beneficially the gratings can be produced in the same length of fiber to increase density.

In FIG. 12 is shown fiber 750 with numerous gratings and a circular modified region 760 within the core 752 and gratings 768 to 764 of various cross sectional sizes within the cladding 754. Due to the smallness of the regions it is possible to inscribe 5, 10 or even 10's of gratings within a single fiber and all within the same length of fiber.

Fibres inscribed with the system inscribed above including those depicted in FIGS. 4 to 12 can be used in strain sensors. Fibres 50 and 150 depicted in FIGS. 5a and 6 have an asymmetrical structure and have different sensitivities to strain in X plane to in the Y plane. When used as a sensor these fibers can be used for selective measuring of strain in a particular plain.

Fibres 250 and 350 depicted in FIGS. 7 and 8 can be made such that the second grating 262, 362 in the Y plane has a slightly different resonant wavelength to the first grating 260, 360 in the X plane. Consequently, they can be used for simultaneous measurement of strain in orthogonal planes. Hence the strain measure can be vectorial. Strain sensors can therefore be created with directly inscribed standard fiber without special measures aimed at improvement of photosensitivity. Consequently strain sensors can be produced relatively cheaply.

Despite the fact that the cores 52, 152, 252, 352, 452 are located symmetrically relative to the geometrical centre of the cross section of the cladding fibers 50, 150, 250, 350, 450 they can also be used as part of a bending sensor. This is because the grating 60 is located asymmetrically relative to the geometrical centre of the cross section of the cladding.

A schematic representation of fiber 50 when bent is shown in FIG. 13, and FIG. 14 shows the side profile of fiber 50. From the FIGS. 12 and 13 it can be seen that grating 60 is a distance d from the centre of the fiber and at angle α from the plane of bending. The spectral shift of the grating resonance can be estimated as

$$Δ λ = \frac{d cos ( α )}{R} λ$$

where λ is the reflective wavelength, R is the radius of the bending curvature.

For example if the distance d is 3 μm and R is 2 cm the wavelength shift is approximately 200 pm. This effect is stronger in long period gratings as they possess greater asymmetry.

Higher order effects such as the elasto-optic effect also contribute to the change in wavelength difference. The sensitivity can be characterised by ΔλR=ηdλ where η represents a sensitivity calibration parameter which equals one in an ideal sensor. In FIG. 14 is shown an experimental plot in which the calibration parameter was estimated to be approximately 0.23.

Use of the fiber illustrated in FIG. 9a in a bending sensor enables the calculation of the difference between the change in wavelength between the two gratings. This can be useful in isolating the changes in the reflected signal caused by the bending from any changes caused by temperature or axial strain.

Particularly beneficial is use of fibers with gratings in orthogonal planes such as fiber 250 shown in FIG. 7. The use of this fiber 250 in a bending sensor allows bending of the fiber in the corresponding orthogonal planes X and Y to be analysed simultaneously so that a three dimensional vectorial bending sensor can be produced.

Use of pairs of gratings in each plane as depicted at fibers 450 in FIG. 10 allows for an increase in sensitivity. Depending on the direction the bend the spectral separation of the gratings will increase or decrease. The direction and strength of the bend can then be accurately monitored by measuring the electrical beat signals of the reflected peaks of the two gratings. Consequently, fiber 450 allows omni-directional measurement of strength and direction of bending in the fiber.

In FIGS. 20 and 21 there is shown two graphs of the spectral shift in a vectorial bending sensor based on a single off axis fiber Bragg grating similar to fiber 50. As can be seen the wavelength significantly decreases with each bend in the fiber and in addition the wavelength increases.

In FIG. 16 is shown transmission spectra at first, second and third order fiber Bragg gratings. These are produced by increasing the scanning speed from 0.53 mm/s to 1.07 mm/s and to 1.605 mm/s. In this example the three gratings have been written in segments of dispersing compensation fiber using a 100× objective 22. It can be seen that the second order grating is the strongest one with peak P3 being considerably larger than peaks P2 or P1.

A further aspect of the invention is the use of voids. The femtosecond laser 12 can be focused with an intensity exceeding the optical damage threshold. The focused laser then removes material and forms a void rather than an area of slightly higher refractive index. The effective refractive index in the waveguide/optical fiber is locally effected by the presence of a void in its vicinity. A series of equally spaced voids placed along the waveguide/fiber produce a periodic change in the effective refractive index in the nearest section of the core and therefore by selecting a suitable period can be used to create a Bragg grating or a long period grating in the same manner as refractive index modulation inscribed above.

Voids are preferably be positioned outside of the core in a position similar to that of fiber 150 depicted in FIG. 5. In such a location the voids do not hinder the transmission of light significantly except for reflection of wavelengths by the effective in the nearest section of the core. An advantage of forming such voids is that they produce a structure ultimately stable against erasure by light and to some extent by temperature. All of the devices inscribed above can be produced by void formation rather than direct change in refractive index simply by positioning the voids in suitable locations to create an area of effective increase of refractive index in the positions of the corresponding modified regions inscribed above.

Alternatively, small voids can be formed inside the core. Although this inevitably results to increased loss, there is also an advantage of having a very high-contrast change of effective refractive index.

As stated above the process can fabricate fiber Bragg gratings into fiber with conventional plastic coating in place around the fiber. Infrared femtosecond inscription relies on multiphoton ionization. As this is a highly nonlinear process, the absorption coefficient, as well as the power thresholds for inscription and ablation, are strongly dependent on the intensity of the beam at a given location. This strong dependence on intensity permits the inscription of buried structures in transparent dielectric materials; it also can be used, under appropriate focusing conditions, for inscription through a material with a lower ablation threshold than that of the processed material. In a beam, focused inside the core or in the vicinity of the core, inscription in or ablation of the core takes place at lower pulse energies than ablation at the surface of the outer coating or damage inside the coating, due to the significantly lower intensity endured by the coating compared to the intensity inside the fiber.

Focusing with a microscopic objective with a numerical aperture NA=0.55 was sufficient to produce gratings in commercial optical fibers without removing the standard plastic coating. The objective used was 100×. The use of correct objective is necessary so that the intensity gradient between the coating and the core is sufficient to exceed the difference between the corresponding inscription thresholds. A low aperture focusing objective may result in ablation of the polymer coating before any change in the core is made. The threshold for altering the coating polymer is usually less than for the core.

The method can be done with the fiber Bragg grating taking up most or all of the core if desired. Consequently fiber gratings can be written through coating, without relying on choice of a particular wavelength, at which the coating is sufficiently transparent or at which the core is sufficiently photosensitive. Indeed it can be done without requiring photosensitization or any other special preparation of the fiber.

The difference in intensity endured by the core and the coating may be estimated considering the focusing conditions. Based on Gaussian optics and the Rayleigh criterion, ω₀=1.22λ/NA, where coo is the diameter of the spot size at focal position, and λ is the laser wavelength, it is possible to estimate the beam radius at any given point along the propagation axis, equation 1;

$$ω ( z ) = {ω}_{o} \sqrt{1 + {( \frac{z}{{z}_{r}} )}^{2}} \qquad ( 1 )$$

Where ω₀ is the beam waist, zᵣ is the Rayleigh range and ω(z) is the beam radius at a given distance, z, along the propagation axis. The beam intensity is inversely proportional to the square of the beam radius (I(z)∝ω⁻²(z)). Considering the focusing conditions, the beam radius at the coating surface (z˜125λm for a standard fiber) is larger than the beam waist (ω₀˜lìm, zᵣ˜4.5ìm) approximately by a factor of 30, assuming an objective with NA=0.55, resulting in the intensity difference by almost three orders of magnitude.

The grating period can be changed by changing the ratio of the translation speed to the pulse repetition rate. Since the cladding is not directly exposed to air, coupling to forward propagating cladding modes is significantly reduced compared to that in bare fiber. A grating can be usually made stronger by increasing the grating length and by using the laser pulses of a higher energy

In all of the fibers depicted above the grating created can be a fiber Bragg grating or a long period grating. Additionally they can be produced in any suitable waveguide rather than an optical fiber. Preferably the gratings and/or regions are created in glass waveguide or fibers

1. An optical fiber or waveguide having a core and a cladding, the fiber/waveguide comprising:
a modified region comprising a modified optical property that differs from an optical property of a surrounding portion of the optical fiber/waveguide, wherein a cross sectional area of the modified region is substantially smaller than a cross sectional area of a core of the fiber or waveguide.

2. An optical fiber or waveguide according to claim 1, wherein the cross sectional area of the modified region is less than any of: (a) half the cross sectional area of the core; (b) a quarter of the cross sectional area of the core; (c) four square micrometeres; or (d) one square micrometre.

3. An optical fiber or waveguide according to claim 1, wherein the modified region is located within the core.

4. An optical fiber or waveguide according to claim 3, wherein the modified region comprises a refractive index that is any of: (a) different from a refractive index of the fiber; or (b) higher than the refractive index of the fiber.

5. An optical fiber or waveguide having a core and a cladding, the fiber/waveguide comprising:
a modified region in the cladding, the modified region having a modified optical property that differs from an optical property of a surrounding portion of the cladding, wherein a non-modified section of the core in a vicinity of the modified region has effective optical properties different to the those of a surrounding portion of the core.

6. An optical fiber or waveguide according to claim 5, wherein the non-modified section of the core has an effective refractive index that is any of: (a) different than that of the surrounding portion of the core; or (b) higher than that of the surrounding portion of the core.

7. An optical fiber or waveguide according to claim 5, wherein the modified region has a different refractive index from that of the cladding.

8. An optical fiber or waveguide according to claim 5, wherein a cross section of the modified region is any of: (a) non-circular; or (b) elliptical.

9. An optical fiber or waveguide according to claim 8 which has linear birefringence resulting from the elliptical cross section.

10. A single polarisation device comprising the fiber or waveguide of claim 8 wherein the cross section of the modified region is highly elliptical.

11. An optical fiber or waveguide according to claim 1, wherein a material in the modified region has been at least partially removed/ablated to form a void.

12. An optical fiber or waveguide according to claim 1, which is cylindrically symmetrical.

13. An optical fiber or waveguide according to claim 1, wherein a geometrical centre of the cross section of the core is substantially coincident with a geometrical centre of a cross section of the cladding.

14. An optical fiber or waveguide according to claim 1, comprising a single core.

15. An optical fiber or waveguide according to claim 1, wherein the modified region comprises a periodic structure.

16. An optical fiber or waveguide according to claim 15, wherein the periodic structure or regions of the core in the vicinity of the periodic structure comprise a first grating.

17. An optical fiber or waveguide according to claim 16 wherein the first grating has a refractive index profile along the core which is substantially non-sinusoidal.

18. An optical fiber or waveguide according to claim 16 wherein the first grating has a refractive index profile comprising regions of higher refractive index separated by regions of substantially constant refractive index.

19. An optical fiber or waveguide according to claim 16, wherein the first grating has a refractive index profile along the core comprising a series of separated regions which are substantially delta function like.

20. An optical fiber or waveguide according to claim 16 wherein the first grating is located in an off-centre segment of fiber so that a profile of the refractive index of the core is asymmetrical and different in different planes of the core cross-section.

21. An optical fiber or waveguide according to claim 20 comprising a second grating in a different off centre segment of fiber to the first grating so that the profile of the refractive index of the core is asymmetric and different in different, preferably orthogonal, planes of the core cross-section.

22. An optical fiber according to claim 16 comprising a plurality of gratings located in different sections/segments of the core, wherein the gratings overlap longitudinally, and are preferably substantially coincident, and are physically separated laterally to prevent physical interaction between the gratings.

23. An optical fiber or waveguide according to claim 22 having any of: (a) more than five longitudinally overlapping gratings; or (b) more than ten longitudinally overlapping gratings.

24. A strain sensor comprising;
an optical fiber according to claim 1; and
a means for measuring an alteration in a reflected wavelength with strain and/or temperature.

25. A direction-sensitive strain sensor comprising:
an optical fiber according to claim 1, wherein a geometrical centre of the cross section of the core is substantially coincident with a geometrical centre of a cross section of the cladding, the modified region comprises a periodic structure that comprises a first grating that is located in an off-centre segment of fiber so that a profile of the refractive index of the core is asymmetrical and different in different planes of the core cross-section; and
a means for measuring an alteration in a reflected wavelength with strain and/or temperature wherein the sensor can be used for selective measurement of strain in a particular plane.

26. A bending sensor comprising:
the optical fiber of claim 1; and
a means for measuring an alteration in a reflected signal with bending of the fiber.

27. A directional bending sensor comprising:
the optical fiber of claim 1, wherein a geometrical centre of the cross section of the core is substantially coincident with a geometrical centre of a cross section of the cladding, the modified region comprises a periodic structure that comprises a first grating that has a refractive index profile comprising regions of higher refractive index separated by regions of substantially constant refractive index, the grating is located in an off-centre segment of fiber so that a profile of the refractive index of the core is asymmetrical and different in different planes of the core cross-section; and
a means for measuring an alteration in reflected wavelength with bending of the fiber, wherein the sensor can be used for determining a direction of bending.

28. A vectorial bending sensor comprising:
the optical fiber of claim 21, wherein the first grating has a refractive index profile along the core comprising a series of separated regions which are substantially delta function like; and
a means for measuring an alteration in reflected wavelength with bending of the fiber, wherein the sensor can be used for determining the direction of bending and wherein two, preferably orthogonal, planes can be analysed simultaneously.

29. A vectorial bending sensor according to claim 28 wherein the optical fiber comprises:
two pairs of gratings, one in each orthogonal plane; and
a means for measuring a change in spectral separation of the gratings with bending allowing omni-directional measurement of strength and/or direction of bending in the fibers.

30. A directional bending sensor according to claim 20, wherein the optical fiber comprises:
a pair of gratings in an orthogonal plane; and
a means for measuring a change in spectral separation of the gratings with bending.

31. A vectorial bending sensor according to claim 28 wherein the spectral separation of the gratings is around 0.2 nm or less.

32. A method of producing a fiber Bragg grating or long period grating, the method comprising:
focussing a pulsed laser beam into a region of the core or of the cladding of a fiber;
using an objective to focus the beam into a spot size, considerably smaller than the core and preferably as small as 1 micrometre or less in diameter, the laser beam being at an intensity sufficient to alter the refractive index of the region;
moving the fiber with the laser still on at a speed relative to the rate of pulsing of the laser such that there is an alteration of the region the spot covers in its first pulse and a separation from the next region which has its refractive index altered by the laser; and
moving the fiber far enough to inscribe a number of separated refractive index altered regions to produce a grating.

33. A method of producing a fiber Bragg grating or long period grating, the method comprising:
focussing a laser beam into a region of the core or of the cladding of a fiber;
using an objective to focus the beam into a spot size, considerably smaller than the core and preferably as small as 1 micrometre in diameter;
keeping the laser beam focussed for sufficient time to alter the refractive index of the region;
moving the fiber with the laser still on, at a speed such that there is an alteration of the region the spot covers; and
repeating the above steps in subsequent new positions of the fiber to produce a grating.

34. A method of producing a fiber Bragg grating or long period grating, the method comprising: the steps of
focussing a pulsed laser beam into a region of the core or of the cladding;
using an objective to focus the beam into a spot size, considerably smaller than the core and preferably as small as 1 micrometre or less in diameter;
keeping the laser beam focussed for sufficient time to alter the refractive index of the region;
then moving the fiber with the laser still on, such that the region is separated from a next region which has its refractive index altered by the laser; and
moving the fiber far enough to inscribe a number of separated refractive index altered regions to produce a grating.

35. A method of producing a fiber Bragg grating or long period grating, the method comprising:
focussing a pulsed laser beam into a region of the core or of the cladding of a fiber which has a coating;
using an objective to focus the beam into the region, the laser beam being at an intensity sufficient to alter the refractive index of the region;
moving the fiber with the laser still on at a speed relative to the rate of pulsing of the laser such that there is an alteration of the region the spot covers in its first pulse and a separation from the next region which has its refractive index altered by the laser; and
moving the fiber far enough to inscribe a number of separated refractive index altered regions to produce a grating.

36. A method of producing a fiber Bragg grating or long period grating, the method comprising:
focussing a laser beam into a region of the core or of the cladding of a fiber which has a coating, using an objective to focus the beam into a region;
keeping the laser beam focussed for sufficient time to alter the refractive index of the region;
moving the fiber with the laser still on, at a speed such that there is an alteration of the region the spot covers; and
repeating the above steps in subsequent new positions of the fiber to produce a grating.

37. A method of producing a fiber Bragg grating or long period grating, the method comprising:
focussing a pulsed laser beam into a region of the core or of the cladding of a fiber which has a coating;
using an objective to focus the beam into the region;
keeping the laser beam focussed for sufficient time to alter the refractive index of the region;
then moving the fiber with the laser still on, such that the region is separated from the next region which has its refractive index altered by the laser; and
moving the fiber far enough to inscribe a number of separated refractive index altered regions to produce a grating.

38. A method of producing a fiber Bragg grating or long period grating according to claim 35 the objective being of sufficient aperture so that an intensity gradient between the coating and the region is sufficient to exceed a difference between corresponding inscription thresholds or where a threshold of surface ablation for the coating is not significantly lower than the core/cladding.

39. A method of producing a fiber Bragg grating or long period grating according to claim 35 wherein a numerical aperture of the objective is 0.55 or greater.

40. A method of producing a fiber Bragg grating or long period grating according to claim 35 wherein the coating is plastic and/or untreated and/or opaque in the visible/UV range.

41. A method according to claim 32 in which the fiber is moved relative to the laser at a constant speed.

42. A method of producing a fiber Bragg grating or long period grating according to claim 32, further comprising reducing the size of the focussed spot by changing the operating wavelength form infra red to visible light or form infra red to ultra violet or fundamental harmonics of the laser to the second or higher harmonics, generated in a non-linear crystal.

43. A method of producing a fiber Bragg grating or long period grating according to claim 32, further comprising reducing the size of the focussed spot by controlling the laser power such that the central part of the beam is above the threshold for inscription of altered refractive index but the edges of the beam remain below the threshold.

44. A method of producing a fiber Bragg grating or long period grating according to claim 32 wherein the laser is focussed at an intensity exceeding the optical damage threshold of the fiber removing matter can creating a void, preferably the beam being focussed outside the core but close enough that the void will alter the effective refractive index of a region of the core.

45. A method of measuring omni-directional measurement of bending in a fiber, the method comprising:
sending light through a fiber optic core with pairs of spectrally separated gratings; and
monitoring a direction and strength by measuring electrical beat signals of reflected peaks of the pairs of gratings as a spectral separation of the gratings varies.

46. A method according to claim 32, wherein the laser is at a wavelength between 600 nm and 1000 rim and preferably around 800 nm.

47. A method according to claim 32, wherein the laser is at infrared or near infra red.

48. The optical fiber or waveguide according of claim 16, wherein the first grating comprises any of a Bragg grating or a long period grating.

49. The method of claim 32, wherein the pulsed laser beam is a femtosecond pulsed laser beam.

50. The method of claim 33, wherein the pulsed laser beam is a femtosecond pulsed laser beam.

51. The method of claim 34, wherein the pulsed laser beam is a femtosecond pulsed laser beam.

52. The method of claim 35, wherein the pulsed laser beam is an ultrashort pulsed laser beam.

53. The method of claim 36, wherein the pulsed laser beam is an ultrashort pulsed laser beam.

54. The method of claim 37, wherein the pulsed laser beam is an ultrashort pulsed laser beam.
